(19) United States
(12) Patent Application Publication
(10) Pub. No.: US 2024/0049487 A1
(43) Pub. Date: Feb. 8, 2024

(54) OPTICAL SENSOR

(71) Applicant: Japan Display Inc., Tokyo (JP)

(72) Inventor: Jun NITTA, Tokyo (JP)

(21) Appl. No.: 18/360,039

(22) Filed: Jul. 27, 2023

(30) Foreign Application Priority Data
Aug. 3, 2022 (JP) 2022-123844

(51) Int. Cl. H10K 30/88; H10K 30/81

(52) U.S. Cl. CPC H10K 30/88; H10K 30/81

(57) ABSTRACT

An optical sensor includes: a plurality of electrodes adjacent to one another; an organic photoelectric conversion layer that includes an active layer and is laminated in common on the plurality of electrodes, the active layer converting incident light into an electric charge; and a light shielding layer covering at least a part of the active layer between the adjacent electrodes on a light receiving side that receives the incident light.

### CROSS-REFERENCE TO RELATED APPLICATION

The present application claims priority from Japanese Application No. 2022-123844 filed on Aug. 3, 2022, the contents of which are hereby incorporated by reference into this application.

### BACKGROUND OF THE INVENTION

### 1. Field of the Invention

The present disclosure relates to an optical sensor.

### 2. Description of the Related Art

In recent years, an optical sensor in which organic photodiodes (OPD) are arranged on a substrate has been known. Such an optical sensor is used as a biometric sensor for detecting biometric information, such as a fingerprint and a vein.

As disclosed in JP2021-125691A and JP2021-57422A, for example, in an optical sensor using OPD, an organic photoelectric conversion layer including an active layer for converting incident light into electric charges is provided in common between pixel electrodes.

### SUMMARY OF THE INVENTION

In the optical sensor having the configuration described above, the electric charge generated between adjacent pixels flows into the pixels, and the contrast is thereby lowered. That is, when such an optical sensor receives light, electric charge is generated also in a portion of the active layer between adjacent pixel electrodes. When the electric charge generated in this manner flows into the portion of the active layer on the pixel electrodes, the contrast decreases.

One or more embodiments of the present invention have been conceived in view of the above, and an object thereof is to provide an optical sensor in which a decrease in contrast caused by a charge generated between adjacent pixels is reduced.

An optical sensor includes: a plurality of electrodes adjacent to one another; an organic photoelectric conversion layer that includes an active layer and is laminated in common on the plurality of electrodes, the active layer converting incident light into an electric charge; and a light shielding layer covering at least a part of the active layer between the adjacent electrodes on a light receiving side that receives the incident light.

### BRIEF DESCRIPTION OF THE DRAWINGS

FIG. 1 is a schematic plan view of an optical sensor according to an embodiment of the present invention;

FIG. 2 is a block diagram showing an example of a configuration of the optical sensor according to the embodiment of the present invention;

FIG. 3 is an enlarged plan view of an area A surrounded by the broken line in FIG. 1;

FIG. 4 is a cross-sectional view of the optical sensor taken along the line B-B of FIG. 1 of the first embodiment;

FIG. 5 is a diagram showing a partial cross section in which FIG. 4 is schematically enlarged;

FIG. 6 is a cross-sectional view of the optical sensor taken along the line B-B of FIG. 1 of the second embodiment; and

FIG. 7 is a cross-sectional view of the optical sensor taken along the line B-B of FIG. 1 of the third embodiment.

### DETAILED DESCRIPTION OF THE INVENTION

Embodiments of the present invention will be described below in detail with reference to the accompanying drawings. In this regard, the present invention is not to be limited to the embodiments described below, and can be changed as appropriate without departing from the spirit of the invention.

The accompanying drawings may schematically illustrate widths, thicknesses, shapes, or other characteristics of each part for clarity of illustration, compared to actual configurations. However, such a schematic illustration is merely an example and not intended to limit the present invention. In this specification and the drawings, some elements identical or similar to those shown previously are denoted by the same reference signs as the previously shown elements, and thus repetitive detailed descriptions of them may be omitted as appropriate.

Further, in the detailed description of the present invention, when a positional relationship between a component and another component is defined, if not otherwise stated, the words “on” and “below” suggest not only a case where the another component is disposed immediately on or below the component, but also a case where the component is disposed on or below the another component with a third component interposed therebetween.

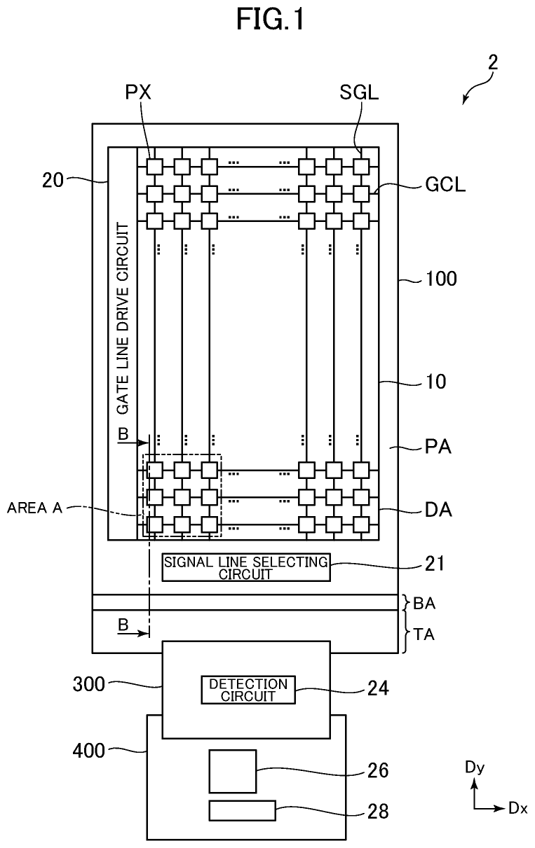

FIG. 1 is a schematic plan view of an optical sensor according to an embodiment of the present invention. As shown in FIG. 1, an optical sensor 2 includes a resin substrate 100, a sensor unit 10, a gate line drive circuit 20, a signal line selecting circuit 21, a detection circuit 24, a control circuit 26, and a power supply circuit 28.

The resin substrate 100 is electrically connected to a control substrate 400 via a flexible printed board 300. The flexible printed board 300 includes the detection circuit 24. The control substrate 400 includes the control circuit 26 and the power supply circuit 28. The control circuit 26 is a field programmable gate array (FPGA), for example. The control circuit 26 supplies control signals to the sensor unit 10, the gate line drive circuit 20, and the signal line selecting circuit 21 so as to control the detection operation of the sensor unit 10. The power supply circuit 28 supplies a power supply voltage to the sensor unit 10, the gate line drive circuit 20, and the signal line selecting circuit 21.

The resin substrate 100 includes a detection area DA and a frame area PA. The detection area DA is an area in which the sensor unit 10 is provided. The frame area PA is an area outside the detection area DA where the sensor unit 10 is not provided. In other words, the frame area PA is an area between the end portion of the detection area DA and the end portion of the resin substrate 100.

The frame area PA has a bending area BA and a terminal area TA. The bending area BA and the terminal area TA are provided at one end of the frame area. Wires connected to the detection area DA are disposed in the bending area BA and the terminal area TA. The resin substrate 100 and the flexible printed board 300 are connected to each other in the terminal area TA.

The sensor unit 10 includes a plurality of pixels PX. The pixels PX are disposed in a matrix in the detection area DA. The pixels PX are photodiodes and respectively output electric signals corresponding to light irradiating the respective photodiodes. Each pixel PX outputs an electric signal corresponding to the light irradiating the pixel PX to the signal line selecting circuit 21 as a detection signal Vdet. In the present embodiment, the optical sensor 2 detects biological data, such as a blood vessel image of a finger and a palm, a pulse wave, a pulse, and a blood-oxygen saturation, based on the detection signal Vdet from each pixel PX. Each pixel PX performs detection in accordance with a gate drive signal Vgcl supplied from the gate line drive circuit 20.

The gate line drive circuit 20 and the signal line selecting circuit 21 are provided in the frame area PA. Specifically, the gate line drive circuit 20 is provided in an area extending along the extending direction (second direction Dy) of a signal line SGL in the frame area PA. The signal line selecting circuit 21 is provided in an area extending along the extending direction (first direction Dx) of a gate line GCL in the frame area PA and is provided between the sensor unit 10 and the bending area BA.

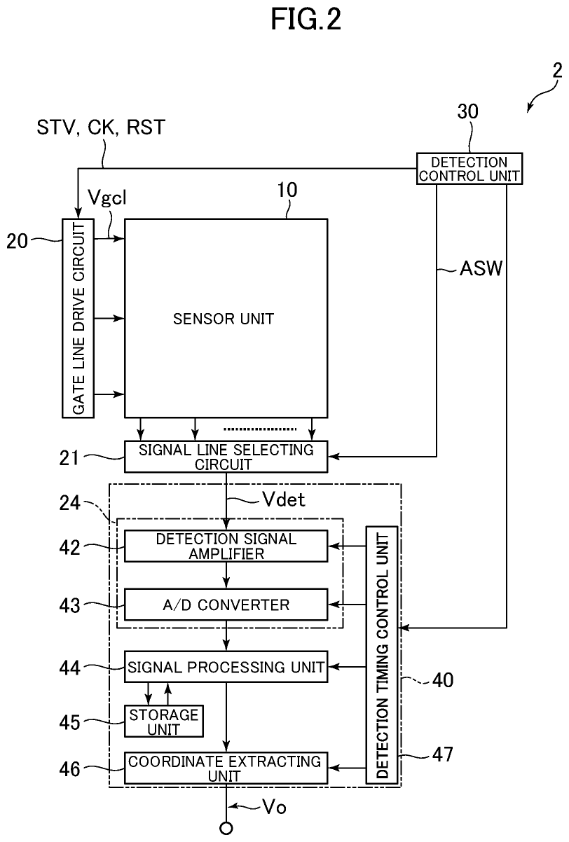

FIG. 2 is a block diagram showing an example of a configuration of the optical sensor according to the embodiment of the present invention. As shown in FIG. 2, the optical sensor 2 further includes a detection control unit 30 and a detection unit 40. Some or all of the functions of the detection control unit 30 are included in the control circuit 26. Further, some or all of the functions of the detection unit 40 other than the detection circuit 24 are included in the control circuit 26.

The detection control unit 30 is a circuit that supplies control signals to the gate line drive circuit 20, the signal line selecting circuit 21, and the detection unit 40, and controls these operations. The detection control unit 30 supplies control signals, such as a start signal STV, a clock signal CK, and a reset signal RST, to the gate line drive circuit 20. The detection control unit 30 supplies control signals, such as a selection signal ASW, to the signal line selecting circuit 21.

The gate line drive circuit 20 drives the gate line GCL based on the control signals. The gate line drive circuit 20 sequentially or simultaneously selects a plurality of gate lines GCL, and supplies a gate drive signal Vgcl to the selected gate line GCL. In this manner, the gate line drive circuit 20 selects a pixel PX connected to the gate line GCL.

The signal line selecting circuit 21 is a switching circuit that sequentially or simultaneously selects a plurality of signal lines SGL. The signal line selecting circuit 21 is a multiplexer, for example. The signal line selecting circuit 21 connects the selected signal line SGL with the detection circuit 24 based on the selection signal ASW supplied from the detection control unit 30. This enables the signal line selecting circuit 21 to output a detection signal Vdet of the pixel PX to the detection unit 40.

The detection unit 40 includes the detection circuit 24, a signal processing unit 44, a storage unit 45, a coordinate extracting unit 46, and a detection timing control unit 47. The detection timing control unit 47 controls the detection circuit 24, the signal processing unit 44, and the coordinate extracting unit 46 to operate in synchronization based on the control signal supplied from the detection control unit 30.

The detection circuit 24 is an analog front end circuit (AFE), for example. The detection circuit 24 is a signal processing circuit having at least functions of a detection signal amplifier 42 and an A/D converter 43. The detection signal amplifier 42 amplifies the detection signal Vdet. The A/D converter 43 converts an analog signal from the detected signal amplifier 42 into a digital signal.

The signal processing unit 44 is a logic circuit that detects a predetermined physical quantity entered into the sensor unit 10 based on the output signal of the detection circuit 24. When a detection target, such as a finger and a palm, comes into contact with or is close to the detection surface, the signal processing unit 44 detects unevenness of the surface of the finger and the palm based on the signal from the detection circuit 24. Further, the signal processing unit 44 detects biological data, such as a blood vessel image of a finger and a palm, a pulse wave, a pulse, and a blood-oxygen saturation, based on a signal from the detection circuit 24.

The storage unit 45 temporarily stores the signal calculated by the signal processing unit 44. The storage unit may be a random access memory (RAM) or a register circuit, for example.

The coordinate extracting unit 46 is a logic circuit that obtains detection coordinates of unevenness of a surface of a finger and a palm, for example, when the signal processing unit 44 detects contact or approach of the finger or the palm. The coordinate extracting unit 46 is a logic circuit that obtains detection coordinates of blood vessels of a finger and a palm, for example. The coordinate extracting unit 46 combines detection signals Vdet from the respective pixels PX of the sensor unit 10 to generate two-dimensional information indicating the shape of the unevenness of the surface of the finger and the palm, for example. The coordinate extracting unit 46 may not calculate the detection coordinates but output the detection signal Vdet as the sensor output Vo.

### FIRST EMBODIMENT

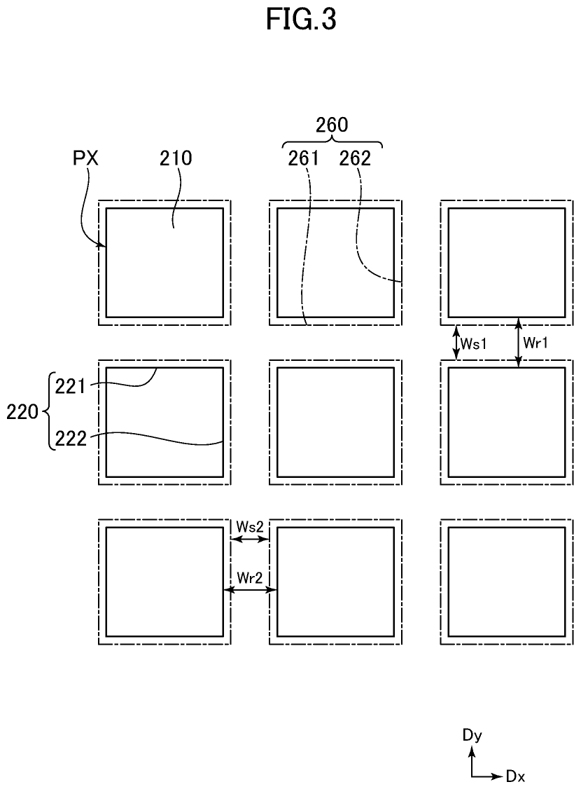

In the following, a first embodiment of the present invention will be described. FIG. 3 is an enlarged plan view of the area A surrounded by the broken line in FIG. 1. The pixels PX are arranged in a matrix so as to be adjacent to each other. Each pixel PX includes a corresponding pixel electrode 210.

In a plan view, each pixel electrode 210 is surrounded by an insulating layer 220. Specifically, in a plan view, the insulating layer 220 includes a row direction extension portion 221 extending in a row direction (in this case, first direction Dx) of the pixels PX and a column direction extension portion 222 extending in a column direction (in this case, second direction Dy) of the pixels PX. In the present embodiment, the pixel PX is square, and thus a width Wr1 of the row direction extension portion 221 of the insulating layer 220 and a width Wr2 of the column direction extension portion 222 are equal to each other. In a plan view, the row direction extension portion 221 and the column direction extension portion 222 intersect each other so as to surround each pixel electrode 210. That is, in a plan view, the insulating layer 220 has a lattice shape so as to surround each of the pixel electrodes 210. Needless to say, the arrangement and the shape of the insulating layer 220 in a plan view are not limited to the above, and various changes can be made in accordance with the arrangement and the shape of the pixels PX.

A light shielding layer 260 is provided between adjacent pixel electrodes 210 so as to overlap with the insulating layer 220 in a plan view. Specifically, in a plan view, the light shielding layer 260 includes a row direction extension portion 261 extending in the first direction Dx and a column direction extension portion 262 extending in the second direction Dy. In the present embodiment, the pixel PX is square, and thus a width Ws1 of the row direction extension portion 261 of the light shielding layer 260 and a width Ws2 of the column direction extension portion 262 are equal to each other. In a plan view, the row direction extension portion 261 and the column direction extension portion 262 intersect each other so as to surround each pixel electrode 210. That is, in a plan view, the light shielding layer 260 has a lattice shape so as to surround each of the pixel electrodes 210. Needless to say, the arrangement and the shape of the light shielding layer 260 in a plan view are not limited to the above, and various changes can be made in accordance with the arrangement and the shape of the pixels PX.

In the present embodiment, the width Ws of the light shielding layer 260 is narrower than the width Wr of the insulating layer 220. More specifically, in a plan view, the width Ws1 of the extending portion 261 in the row direction of the light shielding layer 260 is narrower than the width Wr1 of the row direction extension portion 221 in the row direction of the insulating layer 220. Similarly, in a plan view, the width Ws2 of the column direction extension portion 262 of the light shielding layer 260 is narrower than the width Wr2 of the column direction extension portion 222 of the insulating layer 220. In the present embodiment, the width Ws of the light shielding layer 260 is narrower than the width Wr of the insulating layer 220, although the width Ws of the light shielding layer 260 may be equal to the width Wr of the insulating layer 220.

Such a configuration serves to secure the light shielding effect and prevent the decrease in detection efficiency. That is, when the Ws of the light shielding layer 260 is wider, the light shielding effect is increased, while the detection efficiency is reduced when the light shielding layer 260 extends to a part of the pixel electrode 210 that overlaps with the opening of the insulating layer 220. In this regard, when the width Ws of the light shielding layer 260 is equal to or narrower than the width Wr of the insulating layer 220, it is possible to prevent a decrease in the detection efficiency while achieving a satisfactory light shielding effect.

In the present embodiment, in a plan view, the center of the light shielding layer 260 in the width direction coincides with the center of the insulating layer 220 in the width direction. As such, in a plan view, the light shielding layer 260 covers the center of the insulating layer 220 in the width direction.

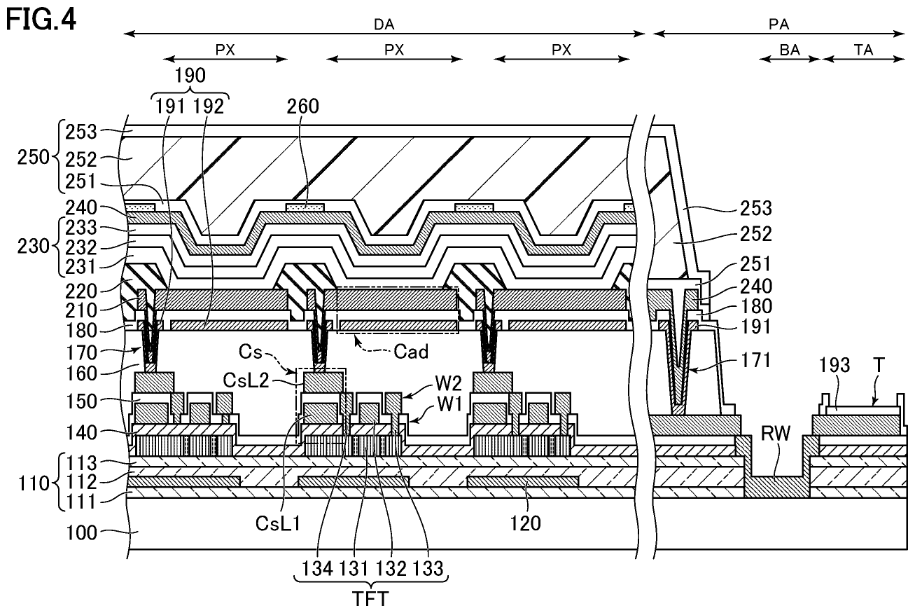

FIG. 4 is a partial cross-sectional view of the optical sensor 2 taken along the line B-B of FIG. 1 of the first embodiment. In FIG. 4, a part of the detection area DA and a part of the frame area PA are shown in a cross-sectional view. As described above, the detection area DA includes a plurality of pixels PX, and the frame area PA includes the bending area BA and the terminal area TA. Each pixel PX includes a corresponding one of the pixel electrodes 210 and a corresponding one of the thin film transistors TFT.

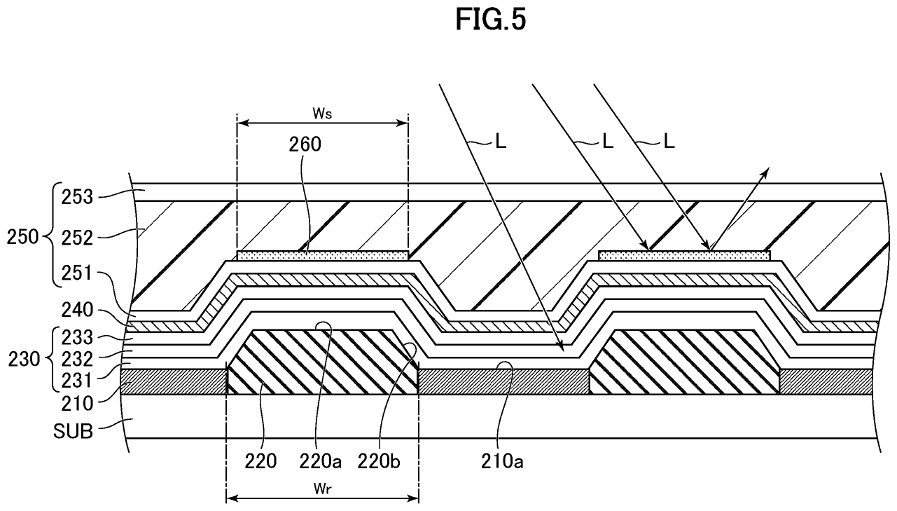

FIG. 4 shows the cut surface in the second direction Dy. When the detection area DA is cut in the first direction Dx, the same cross-sectional configuration as in FIG. 4 is observed. In FIG. 4, hatching of some layers is omitted for clarity of the cross-sectional structure (the same applies to FIGS. 5 to 7). In the following, the cross-sectional structure shown in FIG. 4 will be described in order from the lower layer.

A barrier inorganic film 110 is laminated on the resin substrate 100. The resin substrate 100 is made of polyimide. However, any resin material may be used if the substrate has sufficient flexibility as the sheet-type optical detection device. The barrier inorganic film 110 has a three-layered structure of a first inorganic film (e.g., silicon oxide film) 111, a second inorganic film (e.g., silicon nitride film) 112, and a third inorganic film (e.g., silicon oxide film) 113. The first inorganic film 111 is provided to improve the adhesion to the substrate, the second inorganic film 112 is provided to block moisture and impurities from the outside, and the third inorganic film 113 is provided to prevent hydrogen atoms contained in the second inorganic film 112 from diffusing to the semiconductor layer 131, but the structure is not particularly limited thereto. The structure may include an additional layer, or may be formed of one layer or two layers.

An additional film 120 may be formed at a portion where the thin film transistor TFT to be described later is formed. The additional film 120 prevents a change in characteristics of the thin film transistor TFT due to penetration of light from the back surface of the channel of the thin film transistor TFT or provides a predetermined potential by being formed of a conductive material, thereby providing a back gate effect to the thin film transistor TR. In this case, after the first inorganic film 111 is formed, the additional film 120 is formed in an island shape in accordance with a portion where the thin film transistor TFT is formed, and then the second inorganic film 112 and the third inorganic film 113 are laminated to encapsulate the additional film 120 in the barrier inorganic film 110. However, the present invention is not limited thereto, and the additional film 120 may be first formed on the resin substrate 100 and then the barrier inorganic film 110 may be formed.

A thin film transistor TFT is formed on the barrier inorganic film 110 for each pixel PX. The thin film transistor TFT includes a semiconductor layer 131, a gate electrode 132, a source electrode 133, and a drain electrode 134. Here, a polysilicon thin film transistor is taken as an example, and only an N-channel transistor is shown, although a P-channel transistor may be simultaneously formed. The semiconductor layer 131 of the thin film transistor TFT has a structure in which a low-concentration impurity region or an intrinsic semiconductor region is provided between a channel region and a source/drain region. The gate electrode 132 is a portion where the gate line GCL is electrically connected to the semiconductor layer 131 in each pixel PX. Similarly, the source electrode 133 is a portion where the signal line SGL is electrically connected to the semiconductor layer 131 in each pixel PX.

A gate insulating film 140 is provided between the semiconductor layer 131 and the gate electrode 132. Here, a silicon oxide film is used as the gate insulating film 140. The gate electrode 132 is a part of the first wiring layer W1 formed of MoW. The first wiring layer W1 includes a first holding capacitance line CsL1 in addition to the gate electrode 132. A part of the holding capacitor Cs is formed between the first holding capacitance line CsL1 and the semiconductor layer 131 (source/drain regions) via the gate insulating film 140.

An interlayer insulating film 150 is formed on the gate electrode 132. The interlayer insulating film 150 has a structure in which a silicon nitride film and a silicon oxide film are laminated. The films from the barrier inorganic film 110 to the interlayer insulating film 150 are patterned and removed at the area corresponding to the bending area BA. The polyimide forming the resin substrate 100 is exposed in the area corresponding to the bending area BA. When the barrier inorganic film 110 is patterned to be removed, the surface of the polyimide may be partially eroded or lost.

A wiring pattern is formed under each of the step at the edge of the interlayer insulating film 150 and the step at the edge of the barrier inorganic film 110. A routing wire RW to be formed in the next process is disposed over the wiring pattern when crossing the steps. For example, the gate electrode 132 is disposed between the interlayer insulating film 150 and the barrier inorganic film 110, and the additional film 120 is disposed between the barrier inorganic film 110 and the resin substrate 100. As such, the wiring pattern is formed using these layers.

A second wiring layer W2, which includes the source electrode 133, the drain electrode 134, and a portion serving as the routing wire RW, is formed on the interlayer insulating film 150. Here, a three-layered structure of Ti, Al, and Ti is employed. The first holding capacitance line CsL1 (a part of the first wiring layer W1) and the second holding capacitance line CsL2 (a part of the second wiring layer W2) form another part of the holding capacitor Cs via the interlayer insulating film 150. The routing wire RW extends to the terminal area TA via the bending area BA and forms a terminal portion T to which the flexible printed substrate 300 is connected, for example.

The routing wire RW is formed so as to reach the terminal portion T across the bending area BA, and thus crosses the steps of the interlayer insulating film 150 and the barrier inorganic film 110. As described above, the wiring pattern formed by the additional film 120, for example, is formed in the steps. As such, even if the routing wire RW is disconnected at the recess of the step, the electrical connection can be maintained by contacting the wiring pattern.

A flattening film 160 is disposed so as to cover the source electrode 133, the drain electrode 134, and the interlayer insulating film 150. The flattening film 160 is made of resin, such as photosensitive acryl, because such a material is superior in surface flatness to an inorganic insulating material formed by CVD (chemical vapor deposition), for example. The flattening film 160 is removed in a pixel contact portion 170, a common electrode contact portion 171, the bending area BA, and the terminal area TA.

A transparent conductive film 190 made of indium tin oxide (ITO) is formed on each pixel PX on the flattening film 160. The transparent conductive film 190 includes a first transparent conductive film 191 and a second transparent conductive film 192, which are separated from each other.

In the pixel contact portion 170, the first transparent conductive film 191 covers the second wiring layer W2, a surface of which is exposed by removal of the flattening film 160. An inorganic insulating film (silicon nitride film) 180 is provided on the flattening film 160 so as to cover the first transparent conductive film 191. The inorganic insulating film 180 is open to the pixel contact portion 170.

The second transparent conductive film 192 is disposed below a pixel electrode 210 to be described later (further below the inorganic insulating film 180) and next to the pixel contact portion 170. The second transparent conductive film 192, the inorganic insulating film 36, and the pixel electrode 210 overlap one another and form an additional capacitance Cad.

A third transparent conductive film 193 may be formed on the surface of the terminal portion T. The third transparent conductive film 193 formed on the surface of the terminal portion T may be provided for the purposes of protecting the exposed wiring portion from a damage in a subsequent process.

The laminated structure from the resin substrate 100 to the inorganic insulating film 180 (hereinafter referred to as a substrate SUB) has been discussed. In the following, referring to FIGS. 5 and 4, the structure of layers above the substrate SUB in the first embodiment will be described. FIG. 5 shows a partial cross section in which FIG. 4 is schematically enlarged. The optical sensor 2 according to the first embodiment has a surface irradiation type structure.

A plurality of pixel electrodes 210 adjacent to one another are provided on the substrate SUB (more specifically, the inorganic insulating film 180). Specifically, the pixel electrodes 210 are respectively provided for the pixels PX so as to be electrically connected to the drain electrode 134 through the opening of the inorganic insulating film 180 in the pixel contact portion 170. The pixel electrode 210 is formed as a reflective electrode and has a three-layered structure of an indium zinc oxide film, an Ag film, and an indium zinc oxide film. An indium tin oxide film may be used instead of the indium zinc oxide film. The pixel electrode 210 extends laterally from the pixel contact portion 170 and above the thin film transistor TFT.

An insulating layer 220 having a plurality of openings respectively corresponding to the pixel electrodes 210 is provided on the substrate SUB (more specifically, the inorganic insulating film 180). Similarly to the flattening film 160, the insulating layer 220 is made of photosensitive acrylic, for example. An end portion 220b of the insulating layer 220 is preferably smoothly tapered. If the end portion 220b of the insulating layer 220 is steeply shaped, the coverage defects of the organic photoelectric conversion layer 230 formed thereon is caused.

The organic photoelectric conversion layer 230 is laminated in common on a plurality of pixels PX (i.e., a plurality of pixel electrodes 210) on the pixel electrodes 210. That is, the organic photoelectric conversion layer 230 is provided over the entire detection area DA. More specifically, the organic photoelectric conversion layer 230 is laminated on a surfaces 210a of each of the pixel electrodes 210.

The organic photoelectric conversion layer 230 includes a lower charge transport layer 231, an active layer 232, and an upper charge transport layer 233. More specifically, the organic photoelectric conversion layer 230 has a structure in which the lower charge transport layer 231, the active layer 232, and the upper charge transport layer 233 are laminated in this order from the bottom. The active layer 232 converts incident light L incident on the optical sensor 2 into electric charges. The lower charge transport layer 231 and the upper charge transport layer 233 transport the electric charges generated in the active layer 232. In a case where the surface irradiation type structure is employed, the lower charge transport layer 231 is a hole transport layer and the upper charge transport layer 233 is an electron transport layer, and in a case where the back surface irradiation type structure is employed, the lower charge transport layer 231 is an electron transport layer and the upper charge transport layer 233 is a hole transport layer. The optical sensor 2 of the present embodiment has a surface irradiation type structure, and thus the lower charge transport layer 231 is a hole transport layer, and the upper charge transport layer 233 is an electron transport layer.

The organic photoelectric conversion layer 230 is also disposed on the insulating layer 220. More specifically, the organic photoelectric conversion layer 230 is laminated on a surface 220a and the end portion 220b of the insulating layer 220. The surface 220a of the insulating layer 220 is located above the surface 210a of the pixel electrode 210. Such a structure can prevent leakage of charges between adjacent pixels PX, thereby more reliably preventing the decrease in contrast.

The common electrode 240 is disposed in common on a plurality of pixels PX (i.e. a plurality of pixel electrodes 210) on the organic photoelectric conversion layer 230. That is, the common electrode 240 is disposed over the entire detection area DA similarly to the organic photoelectric conversion layer 230. In the present embodiment, a surface-irradiation type structure is adopted, and thus the common-electrode 240 has a light-transmitting property. Specifically, after PEDOT: PSS is formed on the surface in contact with the organic photoelectric conversion layers 230, the common-electrode 240 is formed using a metallic material such as Ag, Al as a thin film through which the incident light L is transmitted. The common electrode 240 is formed over the organic photoelectric conversion layer 230 provided in the detection area DA and the common electrode contact portion 171 provided in the frame area PA. In the common electrode contact portion 171, the second wiring layer W2 is electrically connected to the routing wire RW and eventually extracted to the terminal portion T.

A sealing layer 250 is laminated on the common electrode 240. One of the functions of the sealing layer 250 is protecting the organic photoelectric conversion layer 230 from moisture entering from the outside, and is required to have a high gas barrier property.

The sealing layer 250 includes a first inorganic material layer 251, a resin layer 252, and a second inorganic material layer 253 in this order from the bottom. More specifically, the sealing layer 250 has a structure in which the first inorganic material layer 251, the resin layer 252, and the second inorganic material layer 253 are laminated in this order from the bottom to the top. In the present embodiment, the first inorganic material layer 251 is a silicon nitride film, the resin layer 252 is an acrylic resin, and the second inorganic material layer 253 is a silicon nitride film. A silicon oxide film or an amorphous silicon layer may be provided between the first inorganic material layer 251 and the resin layer 252 in order to improve the adhesion. In the present embodiment, the sealing layer 250 is provided on the light-receiving surface side, and thus, it is preferable that the materials do not absorb or otherwise act on light of the wavelength to be detected.

The optical sensor 2 includes a light shielding layer 260 that covers at least a part of the active layer 232 between adjacent pixel electrodes 210 on the light receiving side that receives the incident light L. The light shielding layer 260 reflects or absorbs the incident light L so that the incident light L does not enter between adjacent pixel electrodes 210 of the active layer 232. From the viewpoint of preventing a sensing defect caused by the incident light scattered on the light shielding layer 260, the light shielding layer 260 is preferably made of a material having a low reflectance. In the present embodiment, the light shielding layer 260 is made of a black resin, although the present invention is not limited thereto. In the cross-sectional view, the center of the light shielding layer 260 in the width Ws direction also coincides with the center of the insulating layer 220 in the width Wr direction. As such, the light shielding layer 260 also covers the center of the insulating layer 220 in the widthwise Wr in the cross-sectional view. As described with reference to FIG. 4, in the present embodiment, the width Ws of the light shielding layer 260 is narrower than the width Wr of the insulating layer 220.

In the present embodiment, the optical sensor 2 has a surface irradiation type structure, and thus the light-receiving side is an upper side, that is, a side on which the organic photoelectric converter layer 230 is laminated in common on the plurality of pixel electrodes 210 (first side). In other words, in the present embodiment, the light shielding layer 260 covers at least a part of the active layer 231 between adjacent pixel electrodes 210 on the upper side of the active layer 231.

The light shielding layer 260 is preferably close to the active layer 232. This is because when the light shielding layer 260 and the active layer 232 are spaced apart, the incident light L easily enters into the active layer 232 and the light shielding effect is thereby reduced. In this regard, it is preferable that the light shielding layer 260 is laminated on the active layer 232. Needless to say, various other arrangements may be employed. For example, the light shielding layer 260 may be laminated on the upper charge transport layer 233, the common electrode 240, or the sealing layer 250.

In the present embodiment, the light shielding layer 260 is laminated on the first inorganic material layer 251. In a case where the light shielding layer 260 is formed on the first inorganic material layer 251, which is a silicon nitride film, the light shielding layer 260 can be formed by photolithography that enables highly accurate alignment. As such, the light shielding layer 260 is less likely to be mispositioned.

### SECOND EMBODIMENT

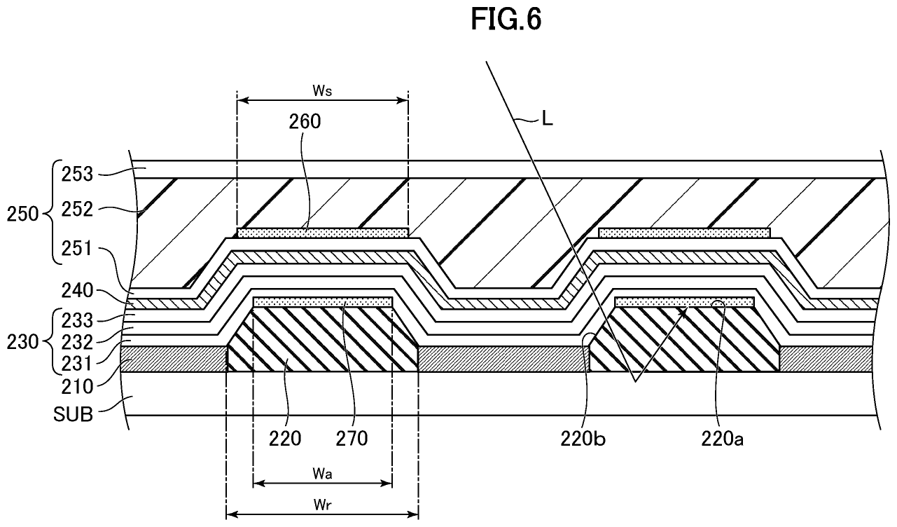

Next, a second embodiment of the present invention will be described. FIG. 6 shows a partial cross section in which the cut surface taken along the line B-B of FIG. 1 according to the second embodiment is schematically enlarged. The optical sensor 2 according to the second embodiment has a surface irradiation type structure similarly to the first embodiment, and thus the light-receiving side is the upper side. In the following, the same structure as that of the first embodiment will not be described.

As shown in FIG. 6, the optical sensor 2 according to the second embodiment is different from that of the first embodiment in that the optical sensor 2 further includes an auxiliary light shielding layer 270 that covers at least a part of the active layer 232 between adjacent pixel electrodes 210 at the lower side, that is, at the side opposite to the side where the organic photoelectric conversion layer 230 is laminated in common on the plurality of pixel electrodes 210 (the second side). In this manner, the auxiliary light shielding layer 270 is provided in addition to the light shielding layer 270, and this serves to more reliably prevent light from entering the active layer 232 between adjacent pixel electrodes 210. In the present embodiment, the width Wa of the auxiliary light shielding layer 270 is narrower than the width Ws of the light shielding layer 260, although the width Wa of the auxiliary light shielding layer 270 may be equal to the width Ws of the light shielding layer 260.

In the present embodiment, the auxiliary light shielding layer 270 is laminated on the insulating layer 220. More specifically, the auxiliary light shielding layer 270 is laminated on the surface 220a of the insulating layer 220. As shown in FIG. 6, the incident light L that is obliquely incident through a part where the organic photoelectric conversion layer 230 overlaps the end portion 220b of the insulating layer 220 may be reflected by the surface of the wiring of the substrate SUB, for example. The incident light L reflected in this manner (so-called stray light) may pass through the insulating layer 220 and enter the active layer 232 between adjacent pixel electrodes 210. In this regard, in the present embodiment, the auxiliary light shielding layer 270 is provided on the insulating layer 220, and thus such stray light can be satisfactorily blocked.

As a modification of the present embodiment, the auxiliary light shielding layer 270 may be formed of the insulating layer 220. Such a structure eliminates the need to separately form the auxiliary light shielding layer 270, thereby preventing an increase in the number of manufacturing steps.

### THIRD EMBODIMENT

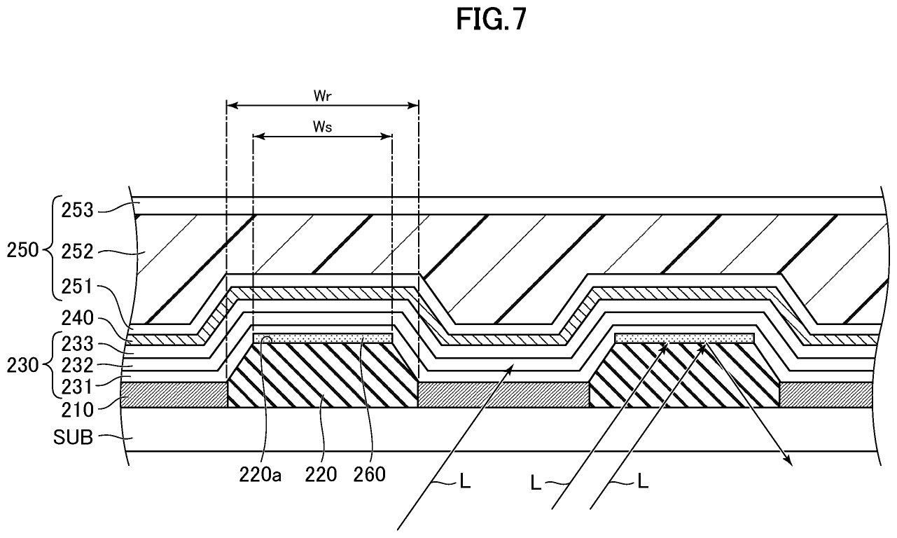

Finally, a third embodiment of the present invention will be described. FIG. 7 shows a partial cross section in which the cut surface taken along the line B-B of FIG. 1 according to the third embodiment is schematically enlarged. In the following, the same structure as that of the first embodiment will not be described.

Unlike the first embodiment and the second embodiment, the optical sensor 2 has a back surface irradiation type structure in the third embodiment. Accordingly, in the present embodiment, the light receiving side is the lower side (second side). In the present embodiment, a back surface irradiation type structure is employed, and thus, a circuit member such as a thin film transistor TFT needs to be disposed at a position not overlapping with the pixel electrode 210 in a plan view or to be made of a translucent material. For the same reason, in the present embodiment, the pixel electrode 210 needs to be formed of a translucent material.

In the present embodiment, the light shielding layer 260 covers at least a part of the active layer 231 between adjacent pixel electrodes 210 on the lower side of the active layer 231. This can prevent the incident light L incident from the lower side from entering the active layer 232 between the adjacent pixel electrodes 210. In the present embodiment as well, the width Ws of the light shielding layer 260 is narrower than the width Wr of the insulating layer 220.

As described for the first embodiment, the light blocking layer 260 is preferably close to the active layer 232. In this regard, the light shielding layer 260 is preferably laminated on the lower charge transport layer 231. Needless to say, various other arrangements may be employed. For example, the light shielding layer 260 may be laminated on the insulating layer 220 and on the substrate SUB, or provided inside the insulating layer 220.

In the present embodiment, the light shielding layer 260 is laminated on the insulating layer 220. More specifically, the light shielding layer 260 is laminated on the surface 220a of the insulating layer 220. In this case, the light shielding layer 260 and the pixel electrode 210 are close to each other, and thus, if there is a patterning defect, the light shielding layer 260 and the pixel electrode 210 may come into contact with each other and cause a short circuit. As such, a material of the light shielding layer 260 may desirably have low conductivity. Specifically, the light shielding layer 260 is formed of a material having lower conductivity than that of the pixel electrode 210. In the present embodiment, similarly to the first embodiment, the light shielding layer 260 is formed of a black resin.

As a modification of the present embodiment, similarly to the second embodiment, the optical sensor 2 may further include an auxiliary light shielding layer that covers at least a part of the active layer 232 between adjacent pixel electrodes 210 on the upper side.

As another modification of the present embodiment, the light shielding layer 260 may be formed of the insulating layer 220. Such a structure eliminates the need to separately form the light shielding layer 260, thereby preventing an increase in the number of manufacturing steps.

The optical sensor according to the present invention described above can keep the processing load low while preventing a decrease in contrast caused by charges generated between adjacent pixels. Known means for preventing an electric charge generated between adjacent pixels from flowing into the pixels include, for example, removing a portion of the organic photoelectric conversion layer between adjacent pixels by patterning and modifying the portion by laser annealing. The present invention can further reduce the processing load compared to these known methods.

The present invention is not limited to the above embodiment, and various modifications can be made. For example, a replacement can be made with a configuration that is substantially the same as the configuration shown in the above-described embodiment, a configuration that exhibits the same operational effect, or a configuration that can achieve the same object.

Within the scope of the idea of the present invention, those skilled in the art can come up with various changes and modifications and it will be understood that these changes and modifications also fall into the scope of the present invention. For example, in each of the above-described embodiments, addition, deletion or redesign of a component, or addition, omission or condition change of a process, which are appropriately made by a person skilled in the art, are also included within the scope of the present invention as long as they remain the gist of the present invention.

1. An optical sensor, comprising:
a plurality of electrodes adjacent to one another;
an organic photoelectric conversion layer that includes an active layer and is laminated in common on the plurality of electrodes, the active layer converting incident light into an electric charge; and
a light shielding layer covering at least a part of the active layer between the adjacent electrodes on a light receiving side that receives the incident light.

2. The optical sensor according to claim 1, wherein
the light shielding layer is formed of a black resin.

3. The optical sensor according to claim 1, further comprising:
a first side where the organic photoelectric conversion layer is laminated in common on the plurality of electrodes and a second side opposite to the first side; and
an insulating layer including a plurality of openings respectively corresponding to the plurality of electrodes, wherein
a surface of the insulating layer on the first side is disposed closer to the first side than a surface of the electrode on the first side, and
the organic photoelectric conversion layer is laminated on the insulating layer on the first side.

4. The optical sensor according to claim 3, wherein
the light receiving side is the first side.

5. The optical sensor according to claim 4, further comprising:
a common electrode that is laminated on the organic photoelectric conversion layer on the first side; and
a sealing layer that is laminated on the common electrode on the first side and includes a first inorganic material layer, a resin layer, and a second inorganic material layer in this order from the second side to the first side, wherein
the light shielding layer is laminated on the first inorganic material layer on the first side.

6. The optical sensor according to claim 4 further comprising an auxiliary light shielding layer that covers at least a part of the active layer between the adjacent electrodes on the second side.

7. The optical sensor according to claim 6, wherein
the auxiliary light shielding layer is laminated on the insulating layer on the first side.

8. The optical sensor according to claim 3, wherein
the light receiving side is the second side.

9. The optical sensor according to claim 8, further comprising an auxiliary light shielding layer that covers at least a part of the active layer between the adjacent electrodes on the first side.

10. The optical sensor according to claim 8, wherein
the light shielding layer is laminated on the insulating layer on the first side.

11. The optical sensor according to claim 10, wherein
the light shielding layer is formed of a material having conductivity lower than conductivity of the electrode.

12. The optical sensor according to claim 8, wherein
the light shielding layer comprises the insulating layer.
